(19) United States
(12) Patent Application Publication
(10) Pub. No.: US 2022/0093528 A1
(43) Pub. Date: Mar. 24, 2022

(54) PACKAGE STRUCTURE AND METHOD FOR MANUFACTURING THE SAME

(71) Applicant: Advanced Semiconductor Engineering, Inc., Kaohsiung (TW)

(72) Inventor: Ian HU, Kaohsiung (TW)

(73) Assignee: Advanced Semiconductor Engineering, Inc., Kaohsiung (TW)

(21) Appl. No.: 17/025,972

(22) Filed: Sep. 18, 2020

(51) Int. Cl. H01L 23/00; H01L 25/18; H01L 23/367; H01L 21/52

(52) U.S. Cl. CPC H01L 23/562; H01L 21/52; H01L 23/367; H01L 25/18

(57) ABSTRACT

A package structure and a method for manufacturing the same are provided. The package structure includes a redistribution structure, a first electronic device, at least one second electronic device, a protection material, a heat dissipation structure and a reinforcement structure. The first electronic device is disposed on the redistribution structure. The second electronic device is disposed on the redistribution structure. The protection material is disposed between the first electronic device and the second electronic device. The heat dissipation structure is disposed on the first electronic device and the second electronic device. The reinforcement structure is disposed in an accommodating space between the heat dissipation structure and the protection material.

### BACKGROUND

### 1. Field of the Disclosure

The present disclosure relates to a package structure and a manufacturing method, and to a package structure including a reinforcement structure, and a method for manufacturing the package structure.

### 2. Description of the Related Art

As for a multi-chip product such as a fan-out chip on substrate (FoCoS) package, a heat sink is attached to semiconductor chips so as to dissipate the heat generated from the semiconductor chips during operation. In the package structure, the semiconductor chips are disposed on a wiring structure (e.g., substrate) and may be covered by an underfill. In general, the coefficients of thermal expansion (CTEs) of the heat sink and the wiring structure are very close and may be greater than the CTEs of the semiconductor chips and the underfill. Also, a hardness of the semiconductor chip is greater than a hardness of the underfill. Thus, in a thermal cycling, the underfill between the semiconductor chips may be delaminated due to unable to withstand the opposite pulling force generated by the heat sink and the wiring structure and further a crack may be formed in the underfill. If the crack extends or grows to reach the wiring structure, the circuit portion in the wiring structure may be damaged or broken, which may result in an open circuit and render the wiring structure inoperative. Thus, a yield of the multi-chip product may decrease.

### SUMMARY

In some embodiments, a package structure includes a redistribution structure, a first electronic device, at least one second electronic device, a protection material, a heat dissipation structure and a reinforcement structure. The first electronic device is disposed on the redistribution structure. The second electronic device is disposed on the redistribution structure. The protection material is disposed between the first electronic device and the second electronic device. The heat dissipation structure is disposed on the first electronic device and the second electronic device. The reinforcement structure is disposed in an accommodating space between the heat dissipation structure and the protection material.

In some embodiments, a method for manufacturing a package structure includes: (a) providing a redistribution structure with a first electronic device, at least one second electronic device and a protection material, wherein the first electronic device and the second electronic device disposed on the redistribution structure, and the protection material is formed between the first electronic device and the second electronic device; (b) bonding a reinforcement structure to the protection material; and (c) attaching a heat dissipation structure to the reinforcement structure, the first electronic device and the second electronic device.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a top view of a package structure according to some embodiments of the present disclosure.

FIG. 2 illustrates a cross-sectional view taken along line A-A of the package structure of FIG. 1.

FIG. 3 illustrates a cross-sectional view taken along line B-B of the package structure of FIG. 1.

FIG. 4 illustrates a top view of an example of a package structure according to some embodiments of the present disclosure.

FIG. 5 illustrates a top view of an example of a package structure according to some embodiments of the present disclosure.

FIG. 6 illustrates a cross-sectional view of an example of a package structure according to some embodiments of the present disclosure.

FIG. 7 illustrates a cross-sectional view of an example of a package structure according to some embodiments of the present disclosure.

FIG. 8 illustrates a cross-sectional view of an example of a package structure according to some embodiments of the present disclosure.

FIG. 9 illustrates a cross-sectional view of an example of a package structure according to some embodiments of the present disclosure.

FIG. 10 illustrates a cross-sectional view of an example of a package structure according to some embodiments of the present disclosure.

FIG. 11 illustrates one or more stages of an example of a method for manufacturing a package structure according to some embodiments of the present disclosure.

FIG. 12 illustrates one or more stages of an example of a method for manufacturing a package structure according to some embodiments of the present disclosure.

FIG. 13 illustrates one or more stages of an example of a method for manufacturing a package structure according to some embodiments of the present disclosure.

FIG. 14 illustrates one or more stages of an example of a method for manufacturing a package structure according to some embodiments of the present disclosure.

FIG. 15 illustrates one or more stages of an example of a method for manufacturing a package structure according to some embodiments of the present disclosure.

FIG. 16 illustrates one or more stages of an example of a method for manufacturing a package structure according to some embodiments of the present disclosure.

FIG. 17 illustrates one or more stages of an example of a method for manufacturing a package structure according to some embodiments of the present disclosure.

FIG. 18 illustrates one or more stages of an example of a method for manufacturing a package structure according to some embodiments of the present disclosure.

FIG. 19 illustrates one or more stages of an example of a method for manufacturing a package structure according to some embodiments of the present disclosure.

FIG. 20 illustrates one or more stages of an example of a method for manufacturing a package structure according to some embodiments of the present disclosure.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for a package structure which has an improved delamination resistance so as to improve a reliability or a yield thereof. At least some embodiments of the present disclosure further provide for techniques for manufacturing the package structure.

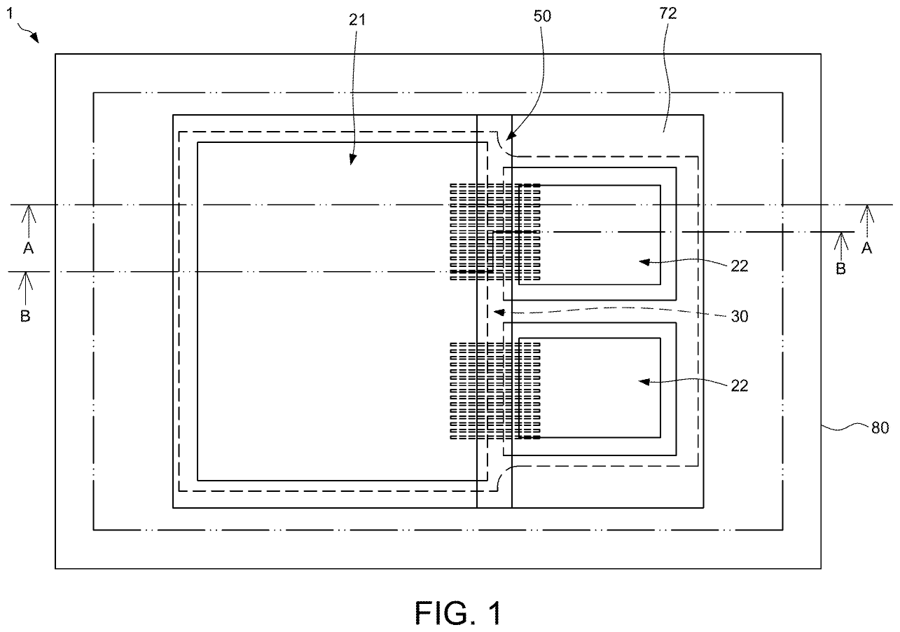

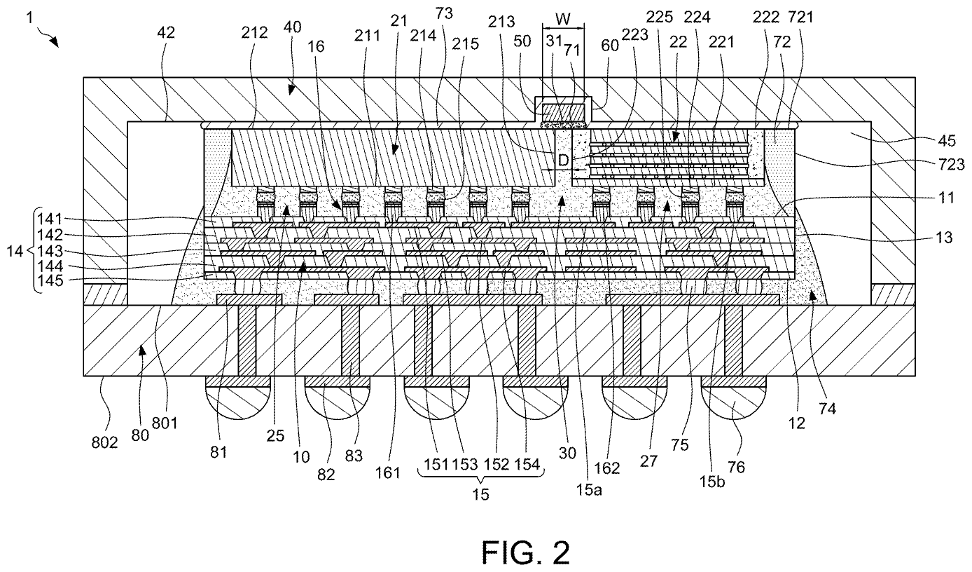

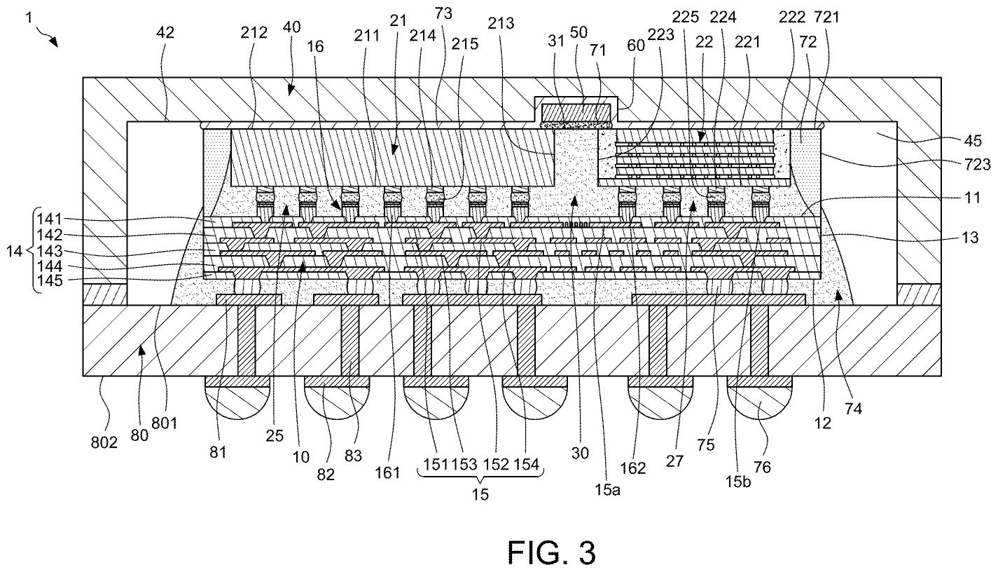

FIG. 1 illustrates a top view of a package structure 1 according to some embodiments of the present disclosure. FIG. 2 illustrates a cross-sectional view taken along line A-A of the package structure of FIG. 1. FIG. 3 illustrates a cross-sectional view taken along line B-B of the package structure of FIG. 1. The package structure 1 includes a redistribution structure 10, a first electronic device 21, at least one second electronic device 22, a first protection material 30, an encapsulant 72, a plurality of solder materials 75, a base substrate 80, a second protection material 74, a reinforcement structure 50, an adhesive material 71, a heat dissipation structure 40, a thermal material 73 and a plurality of external connectors 76. As shown in FIG. 1, the package structure 1 may include one first electronic device 21 and two second electronic devices 22 spaced apart from each other. However, the amounts of the first electronic device(s) 21 and the second electronic device(s) 22 are not limited in the present disclosure.

As shown in FIG. 1 and FIG. 2, the redistribution structure 10 has a first surface 11, a second surface 12 opposite to the first surface 11 and a lateral surface 13 extending between the first surface 11 and the second surface 12. The redistribution structure 10 may include at least one dielectric layer 14, at least one circuit layer 15 in contact with the dielectric layer 14, and a plurality of protrusion pads 16. For example, as shown in FIG. 2 and FIG. 3, the redistribution structure 10 includes a first dielectric layer 141, a first circuit layer 151, a second dielectric layer 142, a second circuit layer 152, a third dielectric layer 143, a third circuit layer 153, a fourth dielectric layer 144, a fourth circuit layer 154, and a fifth dielectric layer 145. That is, the at least one dielectric layer 14 includes the first dielectric layer 141, the second dielectric layer 142, the third dielectric layer 143, the fourth dielectric layer 144 and the fifth dielectric layer 145. The at least one circuit layer 15 includes the first circuit layer 151, the second circuit layer 152, the third circuit layer 153 and the fourth circuit layer 154.

The first dielectric layer 141 may be a topmost dielectric layer or an outermost dielectric layer of the redistribution structure 10. The first circuit layer 151 may be a topmost circuit layer or an outermost circuit layer of the redistribution structure 10. A material of the first circuit layer 151 may include, for example, copper, another conductive metal, or an alloy thereof. A material of the first dielectric layer 141 may include an insulating material, a passivation material, a dielectric material or a solder resist material, such as, for example, a benzocyclobutene (BCB) based polymer or a polyimide (PI). In some embodiments, the first dielectric layer 141 may be made of a photoimageable material. In addition, the first surface 11 of the redistribution structure 10 may be a top surface of the first dielectric layer 141. The first circuit layer 151 is disposed adjacent to the top surface of the first dielectric layer 141. In some embodiments, the first circuit layer 151 is embedded in the first dielectric layer 141, and is exposed from the top surface of the first dielectric layer 141. That is, the first dielectric layer 141 covers the first circuit layer 151, and defines a plurality of openings to expose portions of the first circuit layer 151.

Further, the first circuit layer 151 may include an interconnection portion 15a and a periphery portion 15b. The interconnection portion 15a may be a high density region, and the periphery portion 15b is located outside the high density region (e.g., a low density region). For example, the second electronic device 22 may be electrically connected to the first electronic device 21 through the interconnection portion 15a of the first circuit layer 151. The second electronic device 22 and the first electronic device 21 may be electrically connected to the solder materials 75 on the second surface 12 of the redistribution structure 10 through the periphery portion 15b of the first circuit layer 151. As shown in FIG. 3, a line width/line space (L/S) of the traces of the interconnection portion 15a may be less than an L/S of the traces of the periphery portion 15b. For example, an L/S of the traces of the interconnection portion 15a may be less than or equal to about 5 μm/about 5 μm, or less than or equal to about 2 μm/about 2 μm, or less than or equal to about 0.8 μm/about 0.8 μm. An L/S of the traces of the periphery portion 15b may be less than or equal to about 10 μm/about 10 μm, or less than or equal to about 7 μm/about 7 μm, or less than or equal to about 5 μm/about 5 μm.

The first dielectric layer 141 and the first circuit layer 151 may be disposed on the second dielectric layer 142. In addition, the second dielectric layer 142 may cover the second circuit layer 152. A portion (i.e., a via portion) of the first circuit layer 151 extends through the second dielectric layer 142 to electrically connect the second circuit layer 152. A material of the second dielectric layer 142 may be the same as or similar to the material of the first dielectric layer 141. The second circuit layer 152 may also include an interconnection portion 15a and a periphery portion 15b located outside the interconnection portion 15a. In some embodiments, a plurality of via portions of the first circuit layer 151 may extend from the periphery portion 15b, and they may be formed concurrently and integrally.

Similarly, the second dielectric layer 142 and the second circuit layer 152 may be disposed on the third dielectric layer 143. In addition, the third dielectric layer 143 may cover the third circuit layer 153. A portion (i.e., a via portion) of the second circuit layer 152 extends through the third dielectric layer 143 to electrically connect the third circuit layer 153. A material of the third dielectric layer 143 may be the same as or similar to the material of the second dielectric layer 142. The third circuit layer 153 may also include an interconnection portion 15a and a periphery portion 15b located outside the interconnection portion 15a. In some embodiments, a plurality of via portions of the second circuit layer 152 may extend from the periphery portion 15b, and they may be formed concurrently and integrally.

Similarly, the third dielectric layer 143 and the third circuit layer 153 may be disposed on the fourth dielectric layer 144. In addition, the fourth dielectric layer 144 may cover the fourth circuit layer 154. A portion (i.e., a via portion) of the third circuit layer 153 extends through the fourth dielectric layer 144 to electrically connect the fourth circuit layer 154. A material of the fourth dielectric layer 144 may be the same as or similar to the material of the third dielectric layer 143. The fourth circuit layer 154 may also include an interconnection portion 15a and a periphery portion 15b located outside the interconnection portion 15a.

The fourth dielectric layer 144 and the fourth circuit layer 154 may be disposed on the fifth dielectric layer 145. A portion (i.e., a via portion) of the fourth circuit layer 154 extends through the fifth dielectric layer 145 to be exposed from a bottom surface of the fifth dielectric layer 145 (e.g., the second surface 12 of the redistribution structure 10). A material of the fifth dielectric layer 145 may be the same as or similar to the material of the fourth dielectric layer 144. As shown in FIG. 2, the second electronic device 22 may be electrically connected to the first electronic device 21 through the interconnection portion 15a of the circuit layer 15 (including, for example, the interconnection portions 15a of the first circuit layer 151, the second circuit layer 152, the third circuit layer 153 and the fourth circuit layer 154). The second electronic device 22 and the first electronic device 21 may be electrically connected to the solder materials 75 through the via portions of the periphery portion 15b of the circuit layer 15 (including, for example, the periphery portions 15b of the first circuit layer 151, the second circuit layer 152, the third circuit layer 153 and the fourth circuit layer 154).

The protrusion pads 16 may be disposed on and protrude from the first dielectric layer 141 (i.e., the topmost dielectric layer or the outermost dielectric layer) of the redistribution structure 10. The protrusion pads 16 may be disposed on and protrude from the first surface 11 of the redistribution structure 10, and extend through the first dielectric layer 141 (i.e., the topmost dielectric layer or the outermost dielectric layer) to electrically connect the first circuit layer 151. The protrusion pads 16 may include a plurality of first protrusion pads 161 corresponding to the first electronic device 21 and a plurality of second protrusion pads 162 corresponding to the second electronic device 22.

The first electronic device 21 and the at least one second electronic device 22 are disposed on the first surface 11 of the redistribution structure 10 side by side, and are electrically connected to the circuit layer 15 of the redistribution structure 10. The first electronic device 21 may be a semiconductor device such as an application specific integrated circuit (ASIC) die. As shown in FIG. 2, the first electronic device 21 may have a first active surface 211 (i.e., a bottom surface), a first backside surface 212 (i.e., a top surface) opposite to the first active surface 211, and a lateral surface 213 extending between the first active surface 211 and the first backside surface 212. Further, the first electronic device 21 may include a plurality of first electrical contacts 214 disposed adjacent to the first active surface 211. The first electrical contacts 214 may be exposed or may protrude from the first active surface 211 for electrical connection. The first electrical contacts 214 may be pads, bumps, studs, pillars or posts. In some embodiments, the first electrical contacts 214 of the first electronic device 21 may be electrically connected and physically connected to the first protrusion pads 161 through a plurality of solder materials 215. In other words, the first electronic device 21 may be electrically connected to the redistribution structure 10 by flip-chip bonding. For example, the first electrical contacts 214 may include copper, gold, platinum, and/or other suitable material.

The second electronic device 22 may be a semiconductor device such as high bandwidth memory (HBM) die. As shown in FIG. 2, the second electronic device 22 may have a second active surface 221 (i.e., a bottom surface), a second backside surface 222 (i.e., a top surface) opposite to the second active surface 221, and a lateral surface 223 extending between the second active surface 221 and the second backside surface 222. Further, the second electronic device 22 may include a plurality of second electrical contacts 224 disposed adjacent to the second active surface 221. The second electrical contacts 224 may be exposed or may protrude from the second active surface 221 for electrical connection. The second electrical contacts 224 may be pads, bumps, studs, pillars or posts. In some embodiments, the second electrical contacts 224 of the second electronic device 22 may be electrically connected and physically connected to the second protrusion pads 162 through a plurality of solder materials 225. In other words, the second electronic device 22 may be electrically connected to the redistribution structure 10 by flip-chip bonding. For example, the second electrical contact 224 may include copper, gold, platinum, and/or other suitable material.

The first protection material 30 (i.e., an underfill) is disposed between the first electronic device 21 and the second electronic devices 22, and may extend between the second electronic devices 22. In addition, the first protection material 30 may extend into a first space 25 between the first electronic device 21 and the redistribution structure 10 and into a second space 27 between the second electronic device 22 and the redistribution structure 10 so as to cover and protect the joints formed by the first electrical contacts 214, the first protrusion pads 161 and the solder materials 215, and the joints formed by the second electrical contacts 224, the second protrusion pads 162 and the solder materials 225. In some embodiments, the first protection material 30 may have a top surface 31 substantially coplanar with the first backside surface 212 of the first electronic device 21 and the second backside surface 222 of the second electronic device 22.

The encapsulant 72 covers at least a portion of the first surface 11 of the redistribution structure 10, at least a portion of the first electronic device 21, at least a portion of the second electronic device 22 and the first protection material 30. A material of the encapsulant 72 may be a molding compound with or without fillers. The encapsulant 72 has a first surface 721 (e.g., a top surface) and a lateral surface 723. As shown in FIG. 2, the first surface 721 of the encapsulant 72, the first backside surface 212 of the first electronic device 21, the second backside surface 222 of the second electronic device 22 and the top surface 31 of the first protection material 30 may be substantially coplanar with each other. However, in other embodiments, the top surface 31 of the first protection material 30 may be recessed from the first backside surface 212 of the first electronic device 21 and/or the second backside surface 222 of the second electronic device 22. In addition, the lateral surface 723 of the encapsulant 72 may be substantially coplanar with the lateral surface 13 of the redistribution structure 10.

The solder materials 75 (e.g., solder balls) are disposed adjacent to the second surface 12 of the redistribution structure 10 for external connection. As shown in FIG. 2, the solder materials 75 are disposed on the exposed portions (i.e., the bottom portions of the via portions) of the fourth circuit layer 154.

The base substrate 80 may include a glass reinforced epoxy material (such as FR4), bismaleimide triazine (BT), epoxy resin, silicon, printed circuit board (PCB) material, glass, ceramic or photoimageable dielectric (PID) material. The base substrate 80 may have a first surface 801 and a second surface 802 opposite to the first surface 801. In some embodiments, the base substrate 80 may include a first circuit layer 81, a second circuit layer 82, and a plurality of conductive vias 83. The first circuit layer 81 may be disposed adjacent to the first surface 801 of the base substrate 80, and the second circuit layer 82 may be disposed adjacent to the second surface 802 of the base substrate 80. The conductive vias 83 may extend through the base substrate 80 and electrically connect the first circuit layer 81 and the second circuit layer 82. In some embodiments, as shown in FIG. 2, the redistribution structure 10 may be electrically connected to the first circuit layer 81 of the base substrate 80 through the solder materials 75. In addition, the second protection material 74 (i.e., an underfill) may be further included in a space between the redistribution structure 10 and the base substrate 80 so as to cover and protect the solder materials 75 and the first circuit layer 81.

The reinforcement structure 50 is bonded to the first protection material 30 (e.g., a whole of the top surface 31), a portion of the first electronic device 21 and a portion of the second electronic device 22 through the adhesive material 71. In some embodiments, the reinforcement structure 50 may be dummy. That is, the reinforcement structure 50 may have no electrical function. A material of the reinforcement structure 50 may include metal, polymer, or other suitable material. In addition, a coefficient of thermal expansion (CTE) of the reinforcement structure 50 may be less than CTEs of the first protection material 30 and the redistribution structure 10. In some embodiments, the CTE of the reinforcement structure 50 may be less than about 4 ppm/° C.

The heat dissipation structure 40 is attached to the reinforcement structure 50, and may be disposed on the first electronic device 21 and the second electronic device 22 to dissipate the heat generated from the first electronic device 21 and the second electronic device 22 during operation. In some embodiments, the heat dissipation structure 40 may be attached to the reinforcement structure 50, the first electronic device 21 and the second electronic device 22 through the thermal material 73 (e.g., thermal interface material (TIM)). Further, a bottom portion of the heat dissipation structure 40 may be attached to the first surface 801 of the base substrate 80 through an adhesive material. In some embodiments, the heat dissipation structure 40 may be a cap or hat structure, and may define a cavity 45 for accommodating an assembly structure of the redistribution structure 10, the first electronic device 21, the second electronic devices 22 and the reinforcement structure 50.

To shorten a distance between a bottom surface 42 of the heat dissipation structure 40 and the top surface (i.e., the first backside surface 212) of the first electronic device 21 or between the bottom surface 42 of the heat dissipation structure 40 and the top surface (i.e., the second backside surface 222) of the second electronic device 22, the heat dissipation structure 40 may define a groove recessed from the bottom surface 42 thereof to form an accommodating space 60. The accommodating space 60 is on the heat dissipation structure 40 and between the heat dissipation structure 40 and the first protection material 30, and may correspond to the reinforcement structure 50. Thus, the reinforcement structure 50 may be disposed or embedded in the accommodating space 60 (i.e., the groove of the heat dissipation structure 40). That is, the thermal material 73 may extend into the accommodating space 60 (i.e., the groove of the heat dissipation structure 40) and may cover the reinforcement structure 50.

In some embodiments, a width of the accommodating space 60 (i.e., the groove of the heat dissipation structure 40) may be greater than or equal to about 2 mm, and a depth of the accommodating space 60 (i.e., the groove of the heat dissipation structure 40) may be greater than a thickness of the reinforcement structure 50 by about 100 μm to about 300 μm.

To absorb the opposite pulling force generated by the heat dissipation structure 40 and the redistribution structure 10, a width W of the reinforcement structure 50 may be greater than a spacing D between the first electronic device 21 and the second electronic device 22. In some embodiments, the width W of the reinforcement structure 50 may be greater than the spacing D between the first electronic device 21 and the second electronic device 22 by about 2 mm to about 7 mm. Further, a Young's modulus of the reinforcement structure 50 may be greater than a Young's modulus of the first protection material 30. In some embodiments, the Young's modulus of the reinforcement structure 50 may be greater than or equal to about 50 GPa. In some embodiments, the Young's modulus of the reinforcement structure 50 may be in a range of 50 GPa to 130 GPa.

The Young's modulus of the reinforcement structure 50 is defined as “E”, and the thickness of the reinforcement structure 50 is defined as “t”. To ensure the reinforcement structure 50 has sufficient flexural rigidity, Et^{a} may be greater than about 0.43875 N*mm. In some embodiments, the thickness of the reinforcement structure 50 may be in a range of 100 μm to 300 μm.

The external connectors 76 (e.g., solder balls) are formed or disposed on the second circuit layer 82 of the base substrate 80 for external connection.

In the embodiment illustrated in FIG. 1 to FIG. 3, the reinforcement structure 50 may absorb the opposite pulling force generated by the heat dissipation structure 40 and the redistribution structure 10 so as to prevent the first protection material 30 from being delaminated. Thus, the risk of formation of crack in the first protection material 30 is low. That is, the reinforcement structure 50 may prevent the crack from reaching the redistribution structure 10, and may protect the interconnection portion 15a of the circuit layer 15 from being damaged or broken. Therefore, the reliability and yield of the package structure 1 is improved.

In addition, the reinforcement structure 50 embedded in the accommodating space 60 (e.g., the groove of the heat dissipation structure 40) may shorten the distance between the bottom surface 42 of the heat dissipation structure 40 and the top surface (i.e., the first backside surface 212) of the first electronic device 21 or between the bottom surface 42 of the heat dissipation structure 40 and the top surface (i.e., the second backside surface 222) of the second electronic device 22 to less than about 100 μm. Accordingly, a thermal resistance between the heat dissipation structure 40 and the first electronic device 21 or between the heat dissipation structure 40 and the second electronic device 22 may be reduced to less than about 0.033° C./W.

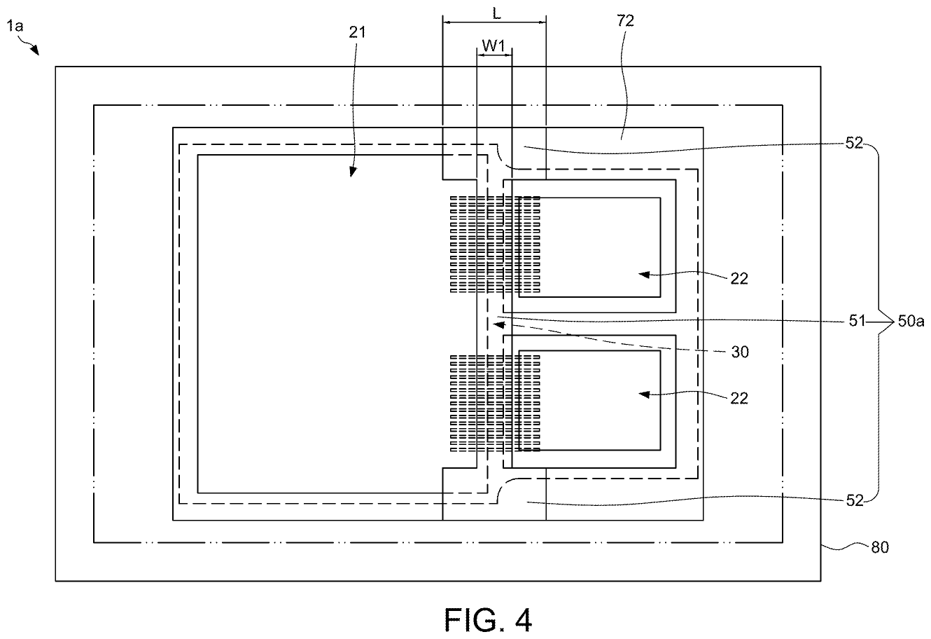

FIG. 4 illustrates a top view of an example of a package structure la according to some embodiments of the present disclosure. The package structure la of FIG. 4 is similar to the package structure 1 of FIG. 1, except for a structure of the reinforcement structure 50a. As shown in FIG. 4, the reinforcement structure 50a includes a beam portion 51 bonded to the first protection material 30 and two first rib portions 52 connected to two ends of the beam portion 51. The function of the beam portion 51 may be the same as the function of the reinforcement structure 50 of FIG. 1. The first rib portions 52 may improve a bending strength of the package structure 1a. In some embodiments, a length L of each of the first rib portions 52 may be greater than a width W1 of the beam portion 51, and the first rib portions 52 may be perpendicular to the beam portion 51. Further, the beam portion 51 and the two first rib portions 52 may be formed concurrently and integrally. As shown in FIG. 4, the reinforcement structure 50a may be in an “I” shape.

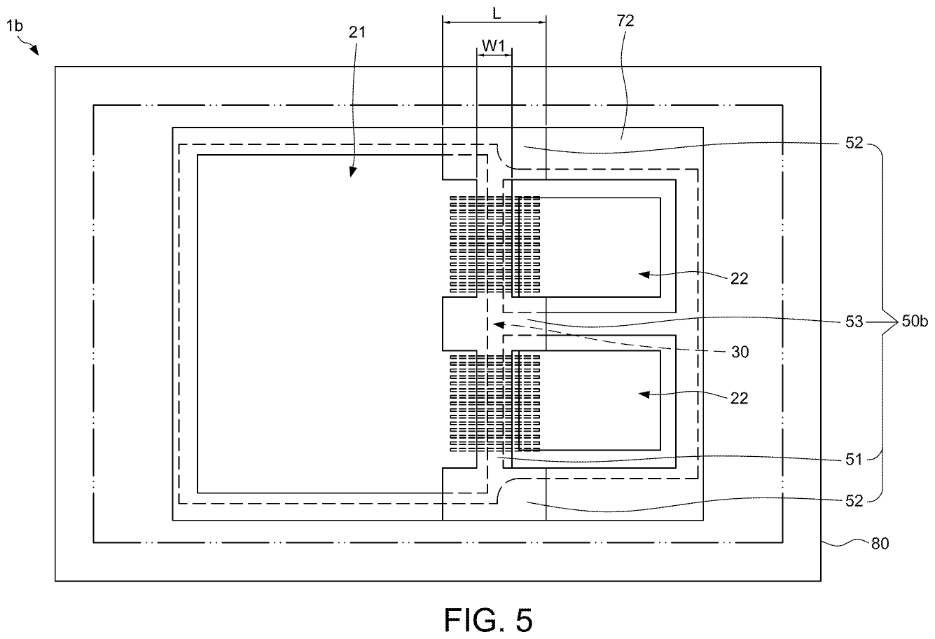

FIG. 5 illustrates a top view of an example of a package structure 1b according to some embodiments of the present disclosure. The package structure 1b of FIG. 5 is similar to the package structure 1a of FIG. 4, except for a structure of the reinforcement structure 50b. As shown in FIG. 5, the reinforcement structure 50b further includes at least one second rib portion 53. The second rib portion 53 is connected to the beam portion 51 and located between the two first rib portions 52. In addition, the second rib portion 53 may be bonded to the first protection material 30 between the second electronic devices 22 to further improve the bending strength of the package structure 1b.

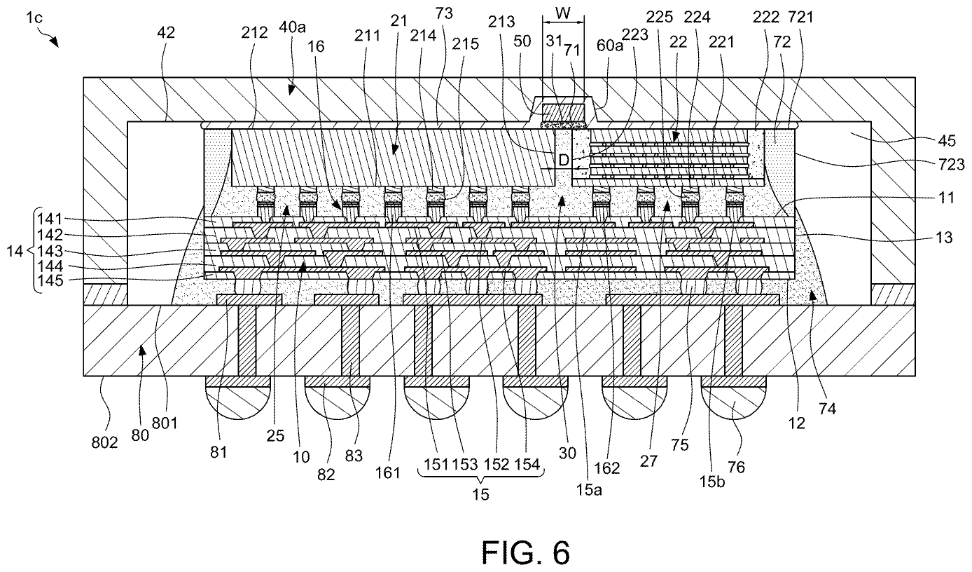

FIG. 6 illustrates a cross-sectional view of an example of a package structure 1c according to some embodiments of the present disclosure. The package structure 1c of FIG. 6 is similar to the package structure 1 of FIG. 2, except for structures of the heat dissipation structure 40a and the accommodating space 60a. As shown in FIG. 6, the groove of the heat dissipation structure 40a may taper upward form the bottom surface 42 of the heat dissipation structure 40a. That is, the accommodating space 60a is trapezoidal in shape, which may improve the alignment and bonding between the reinforcement structure 50 and the accommodating space 60a (i.e., the groove of the heat dissipation structure 40a).

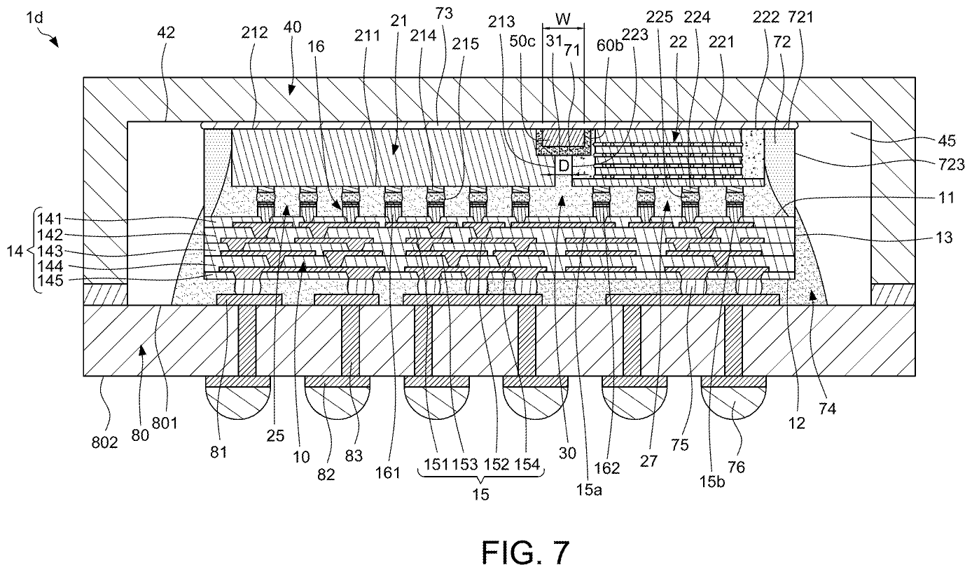

FIG. 7 illustrates a cross-sectional view of an example of a package structure 1d according to some embodiments of the present disclosure. The package structure 1d of FIG. 7 is similar to the package structure 1 of FIG. 2, except for positions of the accommodating space 60b and the reinforcement structure 50c. As shown in FIG. 7, the accommodating space 60b is between the first electronic device 21 and the second electronic device 22. That is, the accommodating space 60b may be a groove recessed between the first electronic device 21 and the second electronic device 22, and the reinforcement structure 50c may be disposed or embedded in the groove and between the first electronic device 21 and the second electronic device 22. Further, the groove may expose a portion (e.g., a top surface) of the first protection material 30, a portion of the first electronic device 21 and a portion of the second electronic device 22. The reinforcement structure 50c may be bonded to the exposed portion (i.e., the top surface) of the first protection material 30, the exposed portion of the first electronic device 21 and the exposed portion of the second electronic device 22 through the adhesive material 71. That is, the adhesive material 71 is disposed in the accommodating space 60b. As shown in FIG. 7, the accommodating space 60b is recesssed from the first surface 721 of the encapsulant 72, the first backside surface 212 of the first electronic device 21, the second backside surface 222 of the second electronic device 22 and a top surface 31 of the first protection material 30. In addition, the entire bottom surface 42 of the heat dissipation structure 40 is flat.

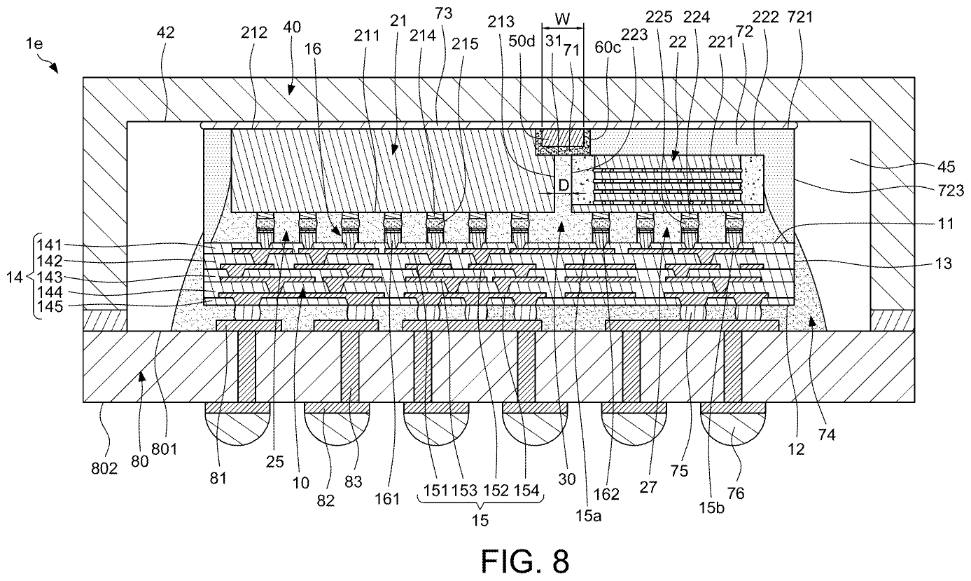

FIG. 8 illustrates a cross-sectional view of an example of a package structure 1e according to some embodiments of the present disclosure. The package structure 1e of FIG. 8 is similar to the package structure 1d of FIG. 7, except for positions of the accommodating space 60c and the reinforcement structure 50d. As shown in FIG. 8, a thickness of the first electronic device 21 is greater than a thickness of the the second electronic device 22, and the second backside surface 222 (i.e., the top surface) of the second electronic device 22 is covered by the encapsulant 72. In addition, the accommodating space 60c is between the first electronic device 21 and the encapsulant 72. That is, the accommodating space 60c may be a groove recessed between the first electronic device 21 and the encapsulant 72, and the reinforcement structure 50d may be disposed or embedded in the groove and between the first electronic device 21 and the encapsulant 72. Further, the groove may expose a portion (e.g., a top surface) of the first protection material 30, a portion of the first electronic device 21 and a portion (e.g., a portion of a top surface) of the second electronic device 22. The reinforcement structure 50d may be bonded to the exposed portion (i.e., the top surface) of the first protection material 30, the exposed portion of the first electronic device 21 and the exposed portion (i.e., the exposed portion of the top surface) of the second electronic device 22 through the adhesive material 71.

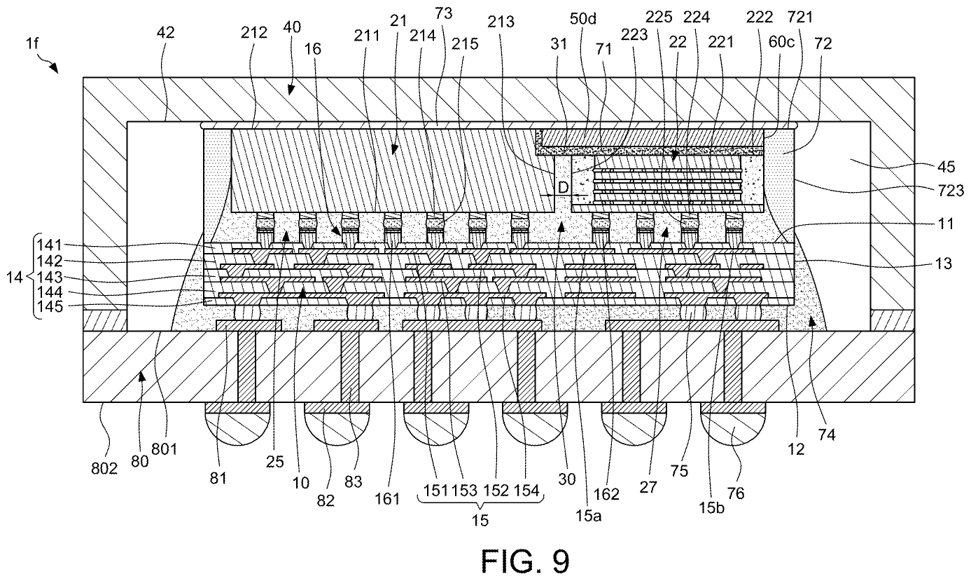

FIG. 9 illustrates a cross-sectional view of an example of a package structure if according to some embodiments of the present disclosure. The package structure 1f of FIG. 9 is similar to the package structure 1e of FIG. 8, except for a size (e.g., a width) of the groove (i.e., the accommodating space 60c) between the first electronic device 21 and the encapsulant 72. As shown in FIG. 9, the size (e.g., the width) of the groove (i.e., the accommodating space 60c) may be greater than the size (e.g., the width) of the second electronic device 22. That is, the groove (i.e., the accommodating space 60c) may expose a whole of the second backside surface 222 (i.e., the top surface) of the second electronic device 22, and the reinforcement structure 50d may be bonded to the whole of the second backside surface 222 (i.e., the top surface) of the second electronic device 22 through the adhesive material 71.

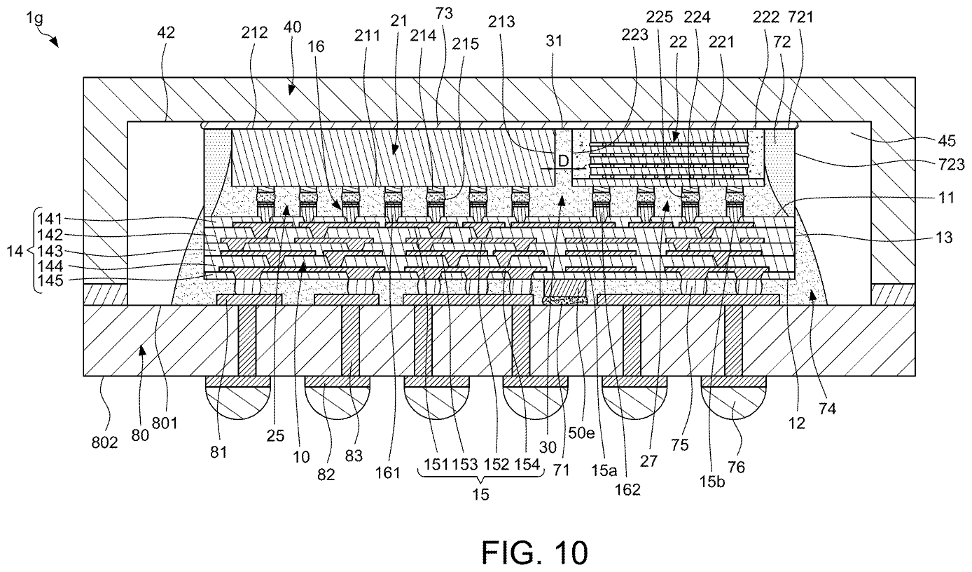

FIG. 10 illustrates a cross-sectional view of an example of a package structure 1g according to some embodiments of the present disclosure. The package structure 1g of FIG. 10 is similar to the package structure 1 of FIG. 2, except for a position of the reinforcement structure 50e. As shown in FIG. 10, the reinforcement structure 50e may be disposed on and bonded to the first surface 801 of the base substrate 80 through the adhesive material 71. In some embodiments, the base substrate 80 may define a groove to accommodate the reinforcement structure 50e.

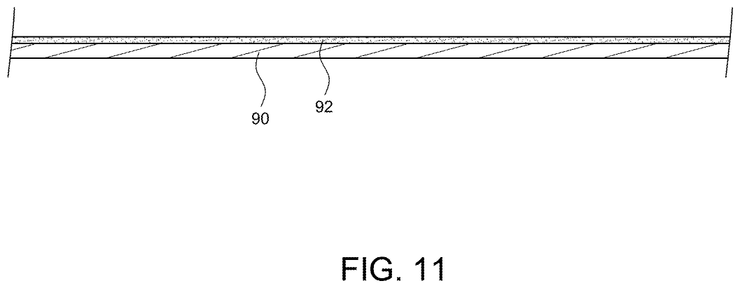

FIG. 11 through FIG. 20 illustrate a method for manufacturing a package structure according to some embodiments of the present disclosure. In some embodiments, the method is for manufacturing the package structure 1 shown in FIG. 1 to FIG. 3.

Referring to FIG. 11, a carrier 90 is provided. The carrier 90 may be in a wafer type or strip type. The carrier 90 may include a release layer 92 disposed thereon.

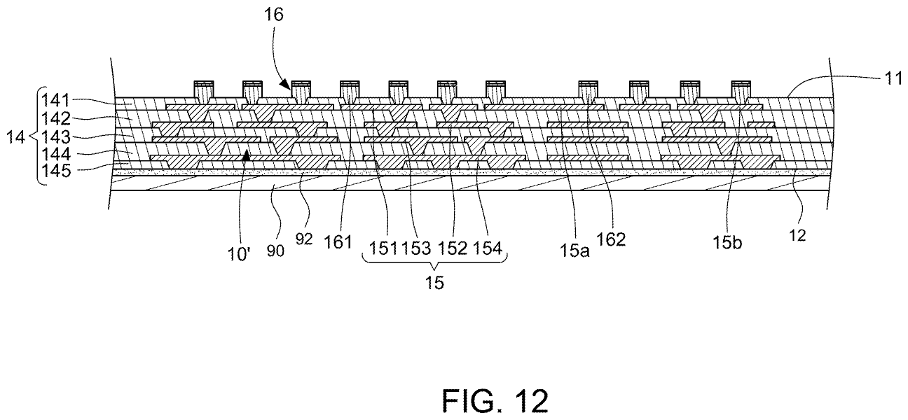

Referring to FIG. 12, a redistribution structure 10′ is formed or disposed on the release layer 92 on the carrier 90. The redistribution structure 10′ of FIG. 12 may be similar to the redistribution structure 10 of FIG. 2 and FIG. 3, and may have a first surface 11 and a second surface 12 opposite to the first surface 11. The redistribution structure 10′ may include at least one dielectric layer 14, at least one circuit layer 15 in contact with the dielectric layer 14 and a plurality of protrusion pads 16. For example, as shown in FIG. 12, the redistribution structure 10′ includes a first dielectric layer 141, a first circuit layer 151, a second dielectric layer 142, a second circuit layer 152, a third dielectric layer 143, a third circuit layer 153, a fourth dielectric layer 144, a fourth circuit layer 154, and a fifth dielectric layer 145. That is, the at least one dielectric layer 14 includes the first dielectric layer 141, the second dielectric layer 142, the third dielectric layer 143, the fourth dielectric layer 144 and the fifth dielectric layer 145. The at least one circuit layer 15 includes the first circuit layer 151, the second circuit layer 152, the third circuit layer 153 and the fourth circuit layer 154.

The first dielectric layer 141 may be a topmost dielectric layer or an outermost dielectric layer of the redistribution structure 10. The first circuit layer 151 may be a topmost circuit layer or an outermost circuit layer of the redistribution structure 10′. Further, the first circuit layer 151 may include an interconnection portion 15a and a periphery portion 15b. The interconnection portion 15a may be a high density region, and the periphery portion 15b is located outside the high density region (e.g., a low density region). A line width/line space (L/S) of the traces of the interconnection portion 15a may be less than an L/S of the traces of the periphery portion 15b.

The protrusion pads 16 may be disposed on and protrude from the first dielectric layer 141 (i.e., the topmost dielectric layer or the outermost dielectric layer) of the redistribution structure 10′. The protrusion pads 16 may be disposed on and protrude from the first surface 11 of the redistribution structure 10′, and extend through the first dielectric layer 141 (i.e., the topmost dielectric layer or the outermost dielectric layer) to electrically connect the first circuit layer 151. The protrusion pads 16 may include a plurality of first protrusion pads 161 and a plurality of second protrusion pads 162.

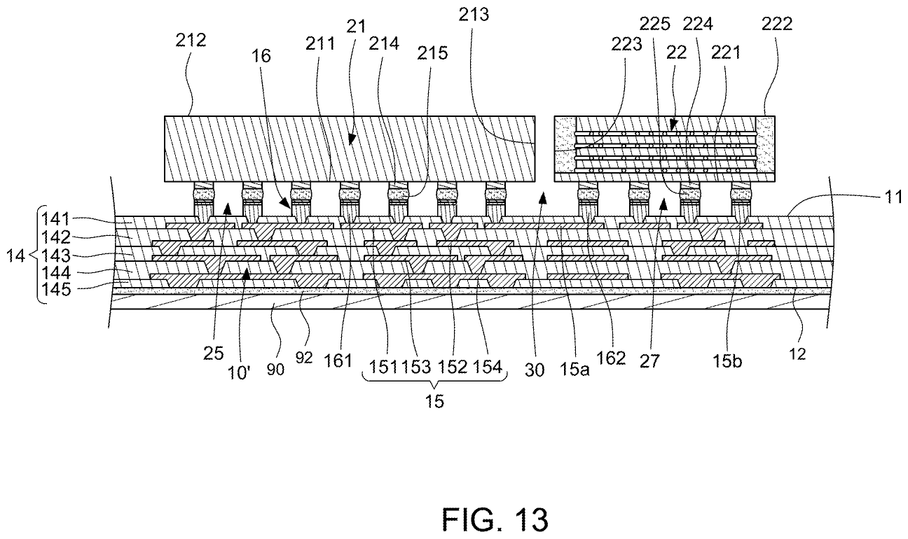

Referring to FIG. 13, a first electronic device 21 and a second electronic device 22 are disposed on and electrically connected to the circuit layer 15 of the redistribution structure 10′ by flip-chip bonding. Thus, the second electronic device 22 may be electrically connected to the first electronic device 21 through the interconnection portion 15a of the circuit layer 15 (including, for example, the interconnection portions 15a of the first circuit layer 151, the second circuit layer 152, the third circuit layer 153 and the fourth circuit layer 154). The first electronic device 21 may have a first active surface 211, a first backside surface 212 opposite to the first active surface 211, and a lateral surface 213 extending between the first active surface 211 and the first backside surface 212. Further, the first electronic device 21 may include a plurality of first electrical contacts 214 disposed adjacent to the first active surface 211. In some embodiments, the first electrical contacts 214 of the first electronic device 21 may be electrically connected and physically connected to the first protrusion pads 161 through a plurality of solder materials 215. The second electronic device 22 may have a second active surface 221, a second backside surface 222 opposite to the second active surface 221, and a lateral surface 223 extending between the second active surface 221 and the second backside surface 222. Further, the second electronic device 22 may include a plurality of second electrical contacts 224 disposed adjacent to the second active surface 221. In some embodiments, the second electrical contacts 224 of the second electronic device 22 may be electrically connected and physically connected to the second protrusion pads 162 through a plurality of solder materials 225.

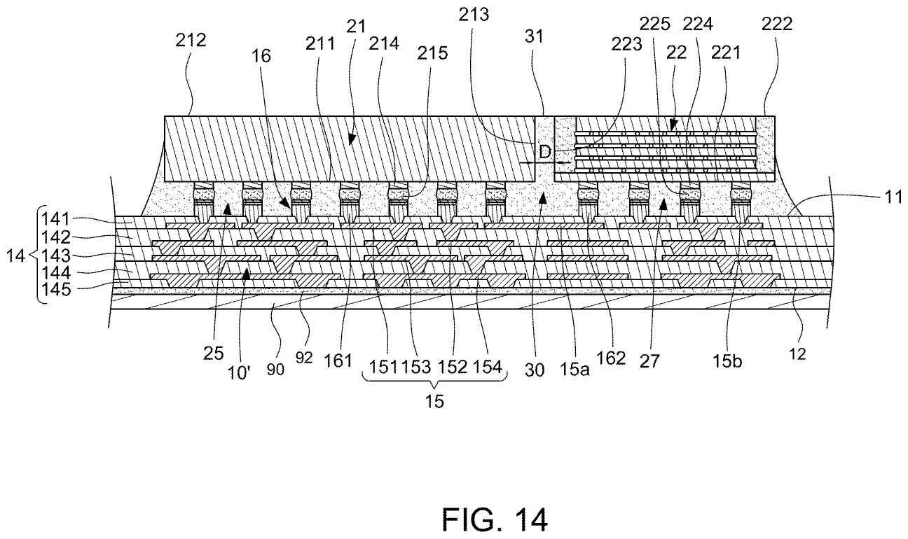

Referring to FIG. 14, a first protection material 30 (i.e., an underfill) is formed or disposed between the lateral surface 213 of the first electronic device 21 and the lateral surface 223 of the second electronic device 22. In addition, the first protection material 30 may further extend into a first space 25 between the first electronic device 21 and the redistribution structure 10′ and a second space 27 between the second electronic device 22 and the redistribution structure 10′ so as to cover and protect the joints formed by the first electrical contacts 214, the first protrusion pads 161 and the solder materials 215, and the joints formed by the second electrical contacts 224, the second protrusion pads 162 and the solder materials 225.

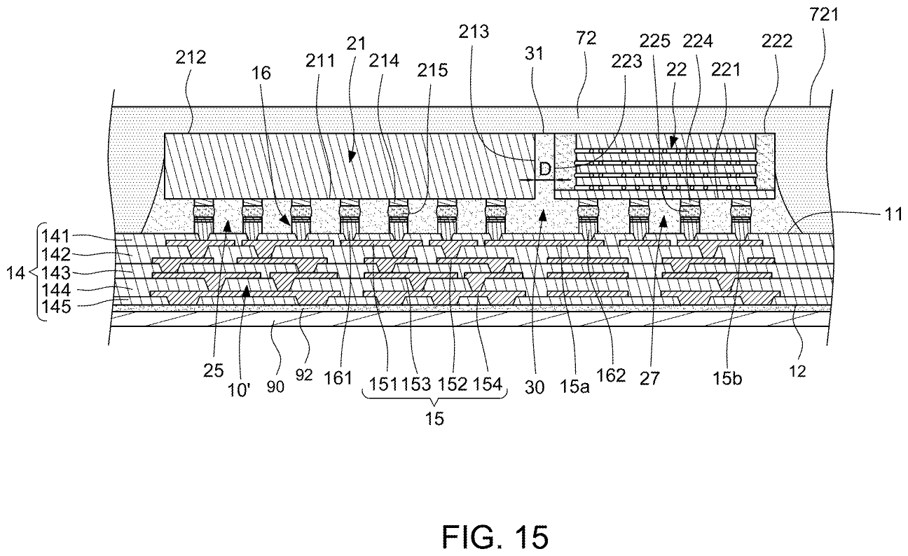

Referring to FIG. 15, an encapsulant 72 is formed or disposed to cover at least a portion of the first surface 11 of the redistribution structure 10′, at least a portion of the first electronic device 21, at least a portion of the second electronic device 22 and the first protection material 30. The encapsulant 72 has a first surface 721 (e.g., a top surface).

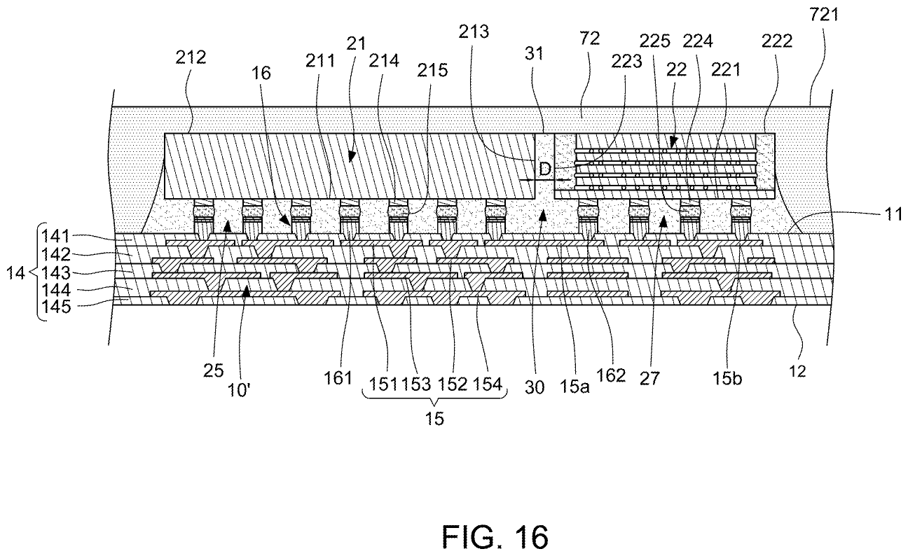

Referring to FIG. 16, the carrier 90 and the release layer 92 are removed. Thus, portions (i.e., the bottom portions of the via portions) of the fourth circuit layer 154 are exposed from the second surface 12 of the redistribution structure 10′.

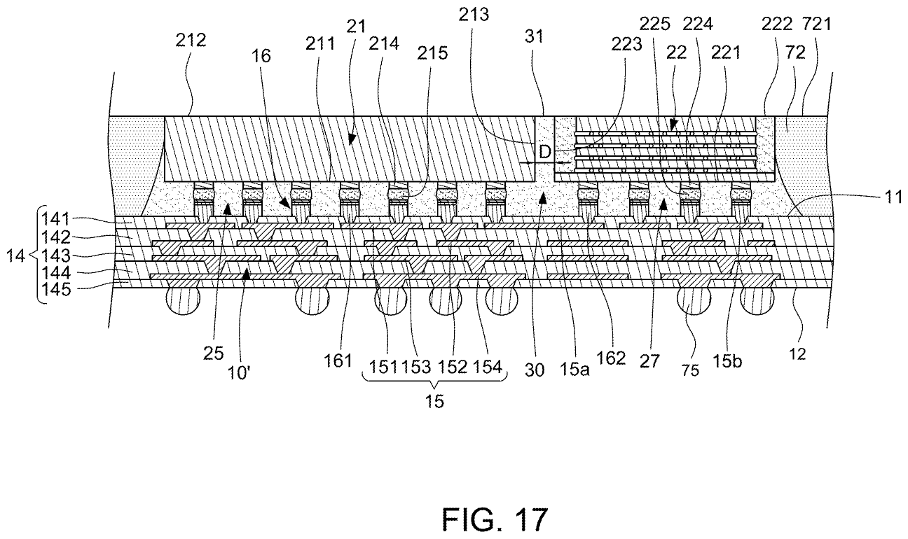

Referring to FIG. 17, the encapsulant 72 is thinned from its first surface 721, and a plurality of solder materials 75 (e.g., solder balls) are formed or disposed to the second surface 12 of the redistribution structure 10′. As shown in FIG. 17, the first surface 721 of the encapsulant 72, the first backside surface 212 of the first electronic device 21, the second backside surface 222 of the second electronic device 22 and a top surface 31 of the first protection material 30 may be substantially coplanar with each other. The solder materials 75 may be disposed on the exposed portions (i.e., the bottom portions of the via portions) of the fourth circuit layer 154.

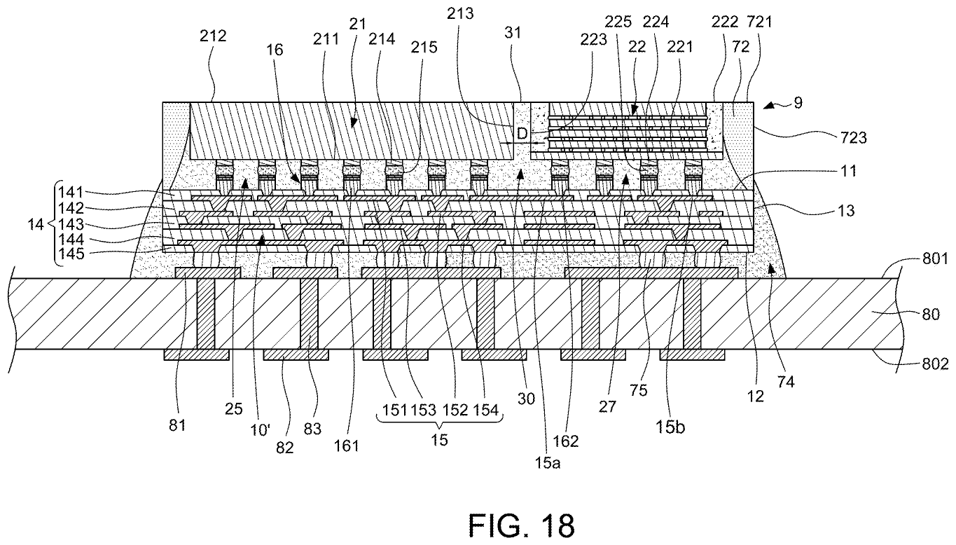

Referring to FIG. 18, a singulation process is conducted to the redistribution structure 10′ so as to obtain a plurality of assembly structures 9, and then the assembly structures 9 are electrically connected to a first circuit layer 81 of a base substrate 80 through the solder materials 75. The base substrate 80 may have a first surface 801 and a second surface 802 opposite to the first surface 801. The base substrate 80 may include a first circuit layer 81, a second circuit layer 82, and a plurality of conductive vias 83. The first circuit layer 81 may be disposed adjacent to the first surface 801 of the base substrate 80, and the second circuit layer 82 may be disposed adjacent to the second surface 802 of the base substrate 80. The conductive vias 83 may extend through the base substrate 80 and electrically connect the first circuit layer 81 and the second circuit layer 82.

Then, a second protection material 74 (i.e., an underfill) is formed or disposed in a space between the assembly structure 9 and the base substrate 80 so as to cover and protect the solder materials 75 and the first circuit layer 81.

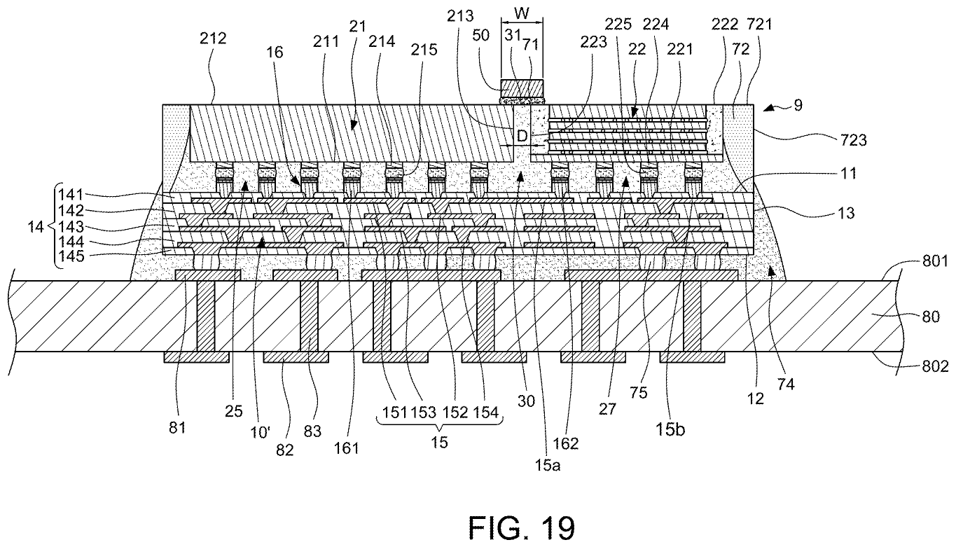

Referring to FIG. 19, a reinforcement structure 50 is bonded to the first protection material 30 (e.g., a whole of the top surface 31), a portion of the first electronic device 21 and a portion of the second electronic device 22 through an adhesive material 71. In some embodiments, the reinforcement structure 50 may be dummy. That is, the reinforcement structure 50 may have no electrical function. In some embodiments, the width W of the reinforcement structure 50 may be greater than a spacing D between the first electronic device 21 and the second electronic device 22 by about 2 mm to about 7 mm.

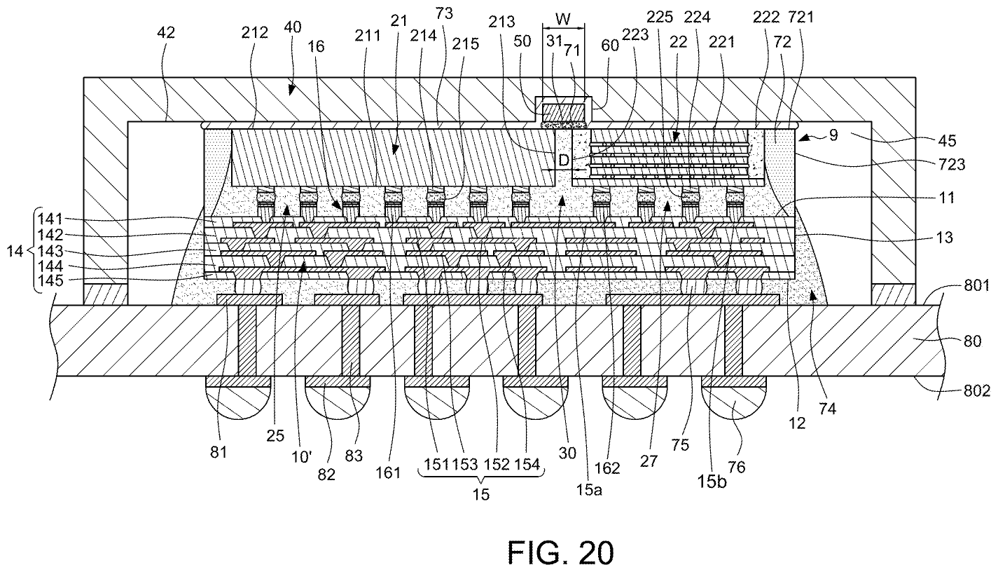

Referring to FIG. 20, a heat dissipation structure 40 is attached to the reinforcement structure 50, the first electronic device 21 and the second electronic device 22 through a thermal material 73 (e.g., thermal interface material (TIM)). In some embodiments, an accommodating space 60 may be formed on the heat dissipation structure 40 for accommodating the reinforcement structure 50. As shown in FIG. 20, a groove may be formed and recessed from a bottom surface 42 of the heat dissipation structure 40 to define the accommodating space 60. Thus, the reinforcement structure 50 may be embedded in the accommodating space 60 (i.e., the groove of the heat dissipation structure 40) to shorten a distance between the bottom surface 42 of the heat dissipation structure 40 and the top surface (i.e., the first backside surface 212) of the first electronic device 21 or between the bottom surface 42 of the heat dissipation structure 40 and the top surface (i.e., the second backside surface 222) of the second electronic device 22.

In some embodiments, the heat dissipation structure 40 may be a cap or hat structure, and may define a cavity 45 for accommodating the assembly structure 9. A portion (e.g., bottom portion) of the heat dissipation structure 40 may be attached to the base substrate 80 through an adhesive material. Then, a plurality of external connectors 76 (e.g., solder balls) may be formed or disposed on the second circuit layer 82 for external connection.

Then, a singulation process may be conducted to the base substrate 80 so as to obtain a plurality of package structures 1 shown in FIG. 2.

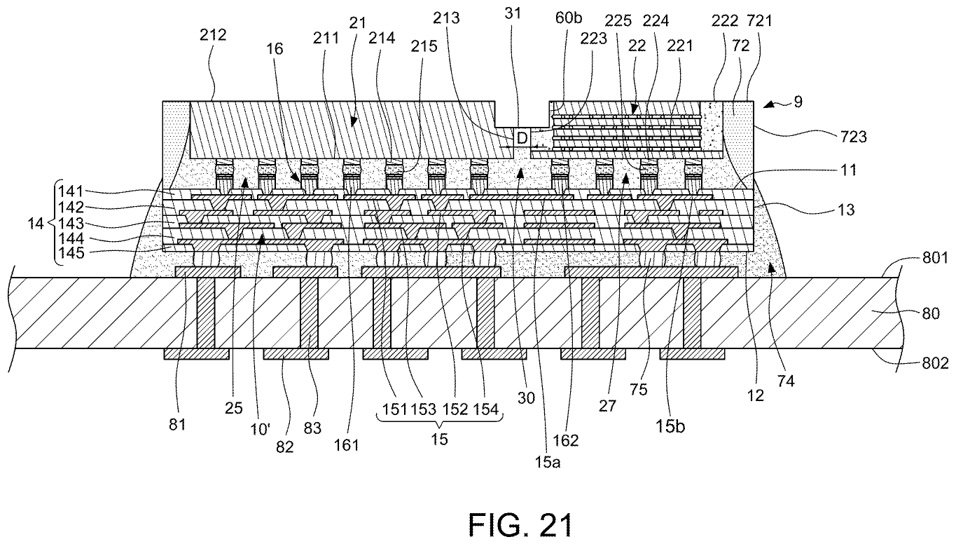

FIG. 21 through FIG. 23 illustrate a method for manufacturing a package structure according to some embodiments of the present disclosure. In some embodiments, the method is for manufacturing the package structure 1d shown in FIG. 7. The initial several stages of the illustrated process are the same as, or similar to, the stages illustrated in FIG. 11 through FIG. 18. FIG. 21 depicts a stage subsequent to that depicted in FIG. 18.

Referring to FIG. 21, an accommodating space (e.g., a groove) 60b is formed and recessed between the first electronic device 21 and the second electronic device 22 by, for example, laser drilling. The accommodating space (i.e., the groove) 60b may expose a portion (e.g., a top surface) of the first protection material 30, a portion of the first electronic device 21 and a portion of the second electronic device 22. That is, a corner portion of the first electronic device 21 is removed to form an indentation portion, and a corner portion of the second electronic device 22 is removed to form an indentation portion. The indentation portions of the first electronic device 21 and the second electronic device 22 together define the accommodating space (e.g., a groove) 60b.

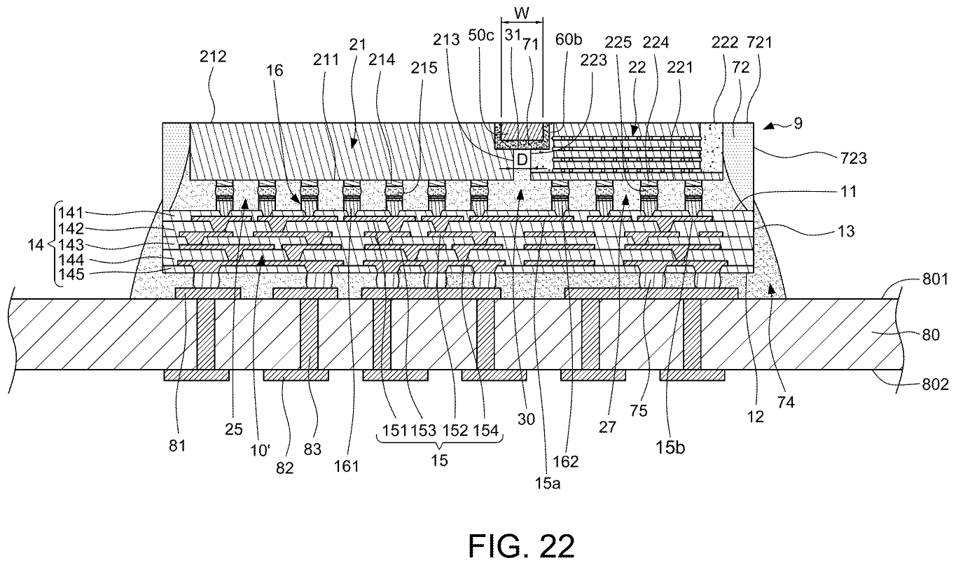

Referring to FIG. 22, a reinforcement structure 50c is embedded in the accommodating space (e.g., groove) 60b and bonded to the exposed portion (i.e., the top surface) of the first protection material 30, the exposed portion of the first electronic device 21 and the exposed portion of the second electronic device 22 through an adhesive material 71.

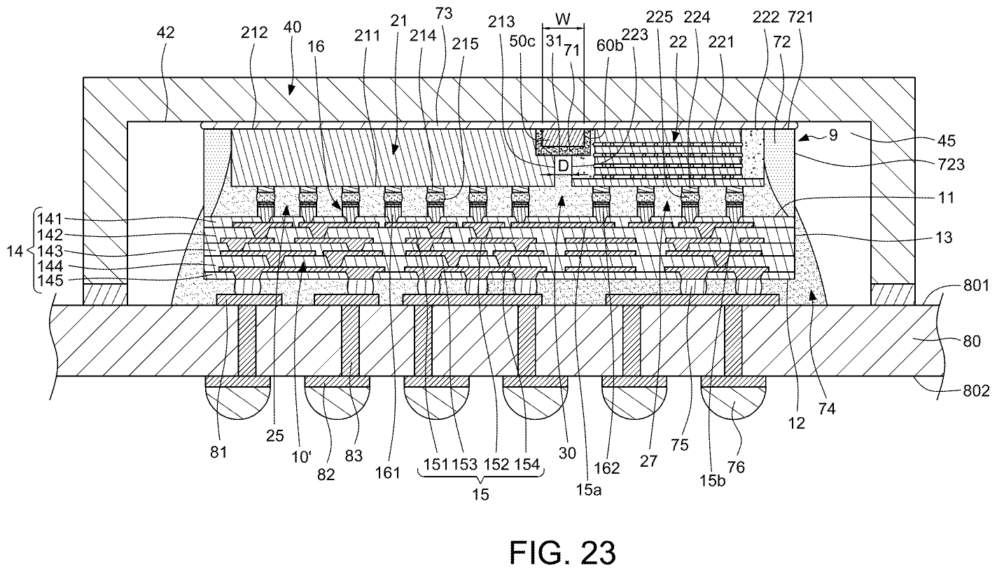

Referring to FIG. 23, a heat dissipation structure 40 is attached to the reinforcement structure 50c, the first electronic device 21 and the second electronic device 22 through a thermal material 73 (e.g., thermal interface material (TIM)). In some embodiments, the heat dissipation structure 40 may be a cap or hat structure, and may define a cavity 45 for accommodating the assembly structure 9. A portion (e.g., bottom portion) of the heat dissipation structure 40 may be attached to the base substrate 80 through an adhesive material. Then, a plurality of external connectors 76 (e.g., solder balls) may be formed or disposed on the second circuit layer 82 for external connection.

Then, a singulation process may be conducted to the base substrate 80 so as to obtain a plurality of package structures 1d shown in FIG. 7.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a redistribution structure;
a first electronic device disposed on the redistribution structure;
at least one second electronic device disposed on the redistribution structure;
a protection material disposed between the first electronic device and the second electronic device;
a heat dissipation structure disposed on the first electronic device and the second electronic device; and
a reinforcement structure disposed in an accommodating space between the heat dissipation structure and the protection material.

2. The package structure of claim 1, wherein the reinforcement structure is bonded to a whole of a top surface of the protection material.

3. The package structure of claim 1, wherein the reinforcement structure is bonded to a portion of the first electronic device and a portion of the second electronic device through an adhesive material.

4. The package structure of claim 1, wherein a width of the reinforcement structure is greater than a spacing between the first electronic device and the second electronic device.

5. The package structure of claim 1, wherein a Young's modulus of the reinforcement structure is greater than a Young's modulus of the protection material.

6. The package structure of claim 1, wherein a Young's modulus of the reinforcement structure is greater than or equal to about 50 GPa.

7. The package structure of claim 1, wherein a depth of the accommodating space is greater than a thickness of the reinforcement structure.

8. The package structure of claim 1, wherein the heat dissipation structure defines a groove recessed from a bottom surface thereof to form the accommodating space.

9. The package structure of claim 1, wherein the accommodating space is a groove recessed between the first electronic device and the second electronic device.

10. The package structure of claim 1, further comprising an encapsulant covering a portion of the first electronic device and a portion of the second electronic device, wherein the accommodating space is a groove recessed between the first electronic device and the encapsulant.

11. The package structure of claim 1, wherein the reinforcement structure includes a beam portion bonded to the protection material and two first rib portions connected to two ends of the beam portion.

12. The package structure of claim 11, wherein a length of each of the first rib portions is greater than a width of the beam portion.

13. The package structure of claim 11, wherein the first rib portions are perpendicular to the beam portion.

14. The package structure of claim 1, wherein the heat dissipation structure is attached to the first electronic device, the second electronic device and the reinforcement structure through a thermal material, and the thermal material extends into the accommodating space and covers the reinforcement structure.

15. A method for manufacturing a package structure, comprising:
(a) providing a redistribution structure with a first electronic device, at least one second electronic device and a protection material, wherein the first electronic device and the second electronic device disposed on the redistribution structure, and the protection material is formed between the first electronic device and the second electronic device;
(b) bonding a reinforcement structure to the protection material; and
(c) attaching a heat dissipation structure to the reinforcement structure, the first electronic device and the second electronic device.

16. The method of claim 15, wherein (c) includes:
(c1) forming an accommodating space on the heat dissipation structure; and
(c2) embedding the reinforcement structure in the accommodating space.

17. The method of claim 16, wherein in (c1), the accommodating space is defined by a groove recessed from a bottom surface of the heat dissipation structure.

18. The manufacturing method of claim 15, wherein (a) includes:
(a1) forming an accommodating space between the first electronic device and the second electronic device; and wherein (b) includes:
(b1) embedding the reinforcement structure in the accommodating space.

19. The manufacturing method of claim 18, wherein in (a1), the accommodating space is defined by a groove recessed between the first electronic device and the second electronic device.

20. The manufacturing method of claim 15, wherein (b) is bonding the reinforcement structure to the protection material, a portion of the first electronic device and a portion of the second electronic device through an adhesive material.
